(19) United States
(12) Patent Application Publication
(10) Pub. No.: US 2004/0022099 A1
(43) Pub. Date: Feb. 5, 2004

(54) FIFO memory and semiconductor device

(75) Inventor: Takashi Ozawa, Kasugai (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: FUJITSU LIMITED

(21) Appl. No.: 10/629,805

(22) Filed: Jul. 30, 2003

(30) Foreign Application Priority Data
Jul. 30, 2002 (JP) 2002-221613

(51) Int. Cl. G11C 29/00

(52) U.S. Cl. 365/200

(57) ABSTRACT

A FIFO memory includes a write counter for updating a write pointer in accordance with a write clock signal and a read counter for updating a read pointer in accordance with a read clock signal. A memory is connected to the write counter and the read counter and has memory cells. The memory performs a write operation for writing data to a memory cell corresponding to the write pointer and a read operation for reading data from a memory cell corresponding to the read pointer. A full flag control circuit generates a full flag synchronously with a write clock signal when the current read pointer and the next write pointer match. An empty flag control circuit generates an empty flag synchronously with a read clock signal when the current write pointer and the next read pointer match.

### CROSS-REFERENCE TO RELATED APPLICATIONS

This application is based upon and claims the benefit of priority from the prior Japanese Patent Application No. 2002-221613, filed on Jul. 30, 2002, the entire contents of which are incorporated herein by reference.

### BACKGROUND OF THE INVENTION

The present invention relates to a FIFO memory and semiconductor device, and specifically relates to a FIFO memory suitable for use when transmitting data between a high-speed operating system and a low-speed operating system.

In general, FIFO (First-In First-Out) memories are often used to transfer data between two systems. FIFO memories are capable of writing and reading data asynchronously, and allow both of the systems doing the data transfer to operate mutually asynchronously (with different operating frequencies). When transferring data between two systems having different operating frequencies, full data capacity and empty data capacity conditions must be monitored in the FIFO memory to reliably prevent overflows and underflows.

FIG. 1 is a block circuit diagram showing the structure of a conventional FIFO memory.

A FIFO memory 111 is provided, for example, between two systems, not shown in the drawing, which transfer data. The operating frequency of each system (the system on the data sending side and the system on the data receiving side) connected to the FIFO memory 111 is mutually different, and both systems respectively operate asynchronously.

The FIFO memory 111 is provided with a memory 112 for holding the data transferred between both systems, write counter 113, read counter 114, comparison circuit 115, and flag generation/cancellation circuit 116.

The memory 112 is a two-port memory provided with a write port for writing data output from one system (data sending side), and a read port for reading the data stored in the memory 112 and supplying the data to another system (data receiving side). This memory 112 reads the data stored in the memory 112 in the sequence in which the data were written.

The write counter 113 inputs a write clock signal WCK specifying the operating frequency of the system on the data sending side, and generates a write pointer WQ indicating the address of the memory 112 when the data is written. Specifically, the write counter 113 increments the write pointer WQ for each input of a write clock signal WCK, and outputs the same to the memory 112, and the memory 112 writes data to the memory cell (not shown in the drawing) at the address corresponding to the write pointer WQ.

Similarly, the read counter 114 inputs a read clock signal RCK specifying the operating frequency of the system on the data receiving side, and generates a read pointer RQ indicating the address of the memory 112 when data is read. Specifically, the read counter 114 increments the read pointer RQ for each input of a read clock signal RCK, and outputs the same to the memory 112, and the memory 112 reads data from the memory cell (not shown in the drawing) at the address corresponding to the read pointer RQ.

Furthermore, the counters 113 and 114 are ring counters (i.e., the count number is identical for each counter 113 and 114) constructed so as to again output the initial pointer signals WQ and RQ after respectively outputting a predetermined number of pointer signals WQ and RQ.

The comparison circuit 115 compares the write pointer WQ output from the write counter 113 when data is written with the read pointer RQ at that time, and determines whether or not the pointers WQ and RQ match. Furthermore, the comparison circuit 115 compares the read pointer RQ output from the read counter 114 when data is read with the write pointer WQ at that time, and determines whether or not the pointers RQ and WQ match.

The flag generation/cancellation circuit 116 generates a full flag FF indicating the full capacity condition of the data stored in the memory 112, or generates an empty flag EF indicating the empty capacity condition of the data stored in the memory 112, in response to a detection signal output from the comparison circuit 115.

By way of detailed explanation, the flag generation/cancellation circuit 116 generates a full flag FF in response to a detection signal from the comparison circuit 115 when the comparison circuit 115 detects that the write pointer WQ and read pointer RQ mutually match during a write operation. The write counter 113 stops operating in response to the full flag FF. Conversely, the flag generation/cancellation circuit 116 generates an empty flag EF in response to the detection signal from the comparison circuit 115 when the comparison circuit 115 detects that the read pointer RQ and the write pointer WQ mutually match during a read operation. The read counter 114 stops operating in response to the empty flag EF.

In the case of two systems connected by such a FIFO memory 111, there are, for example, more write operations than read operations when the operating frequency of the system on the data sending side is higher than the operating frequency of the system on the data receiving side.

As a result, the data written to the memory 112, but not yet read, gradually increase, such that there is a lack of addresses within the memory 112 at which new data can be written, and the memory 112 reaches a full capacity condition. Then, in this condition, the write pointer WQ output from the write counter 113 matches the read pointer RQ, and the flag generation/cancellation circuit 116 outputs a full flag FF. In this way, the write counter 113 stops operating, and the writing operation to the memory 112 is prohibited. This full condition of the memory 112 continues until the data read operation is performed thereafter to such point that addresses to which new data can be written (specifically, writable over existing data) are secured in the memory 112.

Conversely, more read operations are performed than write operations when the operating frequency of the system on the data receiving side is higher than the operating frequency of the system on the data sending side. As a result, although written to the memory 112, the as yet unread data gradually decrease until finally there are no data remaining to be read in the memory 112, and the memory 112 is in an empty condition. Then, in this condition, the read pointer RQ output from the read counter 114 matches the write pointer WQ, and the flag generation/cancellation circuit 116 outputs an empty flag EF. In this way, the read counter 114 stops operating, and the read operation from the memory 112 is prohibited. The empty condition of the memory 112 continues until the data write operation is performed thereafter to such point that addresses from new data can be read are generated in the memory 112.

In the case of such a FIFO memory 111, data loss occurs due to overwriting as yet unread data when the write operation continues regardless of the full condition of the memory 112, producing an overflow condition in the memory 112. Conversely, previously read data is re-read when the read operation continues regardless of the empty state of the memory 112, producing an underflow condition in the memory 112.

When these overflows and underflows are generated, data transfer is not performed correctly and transfer errors occur. Therefore, the FIFO memory 111 monitors the condition of the memory 112 during data transfer, and detects the data full condition and data empty condition so as to prevent the occurrence of the aforesaid overflow and underflow before they occur.

In conventional FIFO memories, the delay time until the full flag FF indicating a full capacity condition and empty flag EF indicating an empty capacity condition of the memory 112 are actually output from the flag generation/cancellation circuit 116 is dependent on the delay time of each of the counters 113, 114, comparison circuit 115, and flag generation/cancellation circuit 116. Therefore, there is a long delay in the output of the full flag FF and the empty flag EF.

The full flag FF and the empty flag EF become the decision criterion for the operation of the next cycle. Accordingly, overflow and underflow may be generated because, when there is a long delay in the output of the flag FF and flag EF, there is a delay in the determination of whether or not to perform the write operation and read operation of the next operation cycle. Therefore, in order to avoid generation of these overflows and underflows, it becomes necessary to reduce the operating frequency of the high-speed operating system, which results in disadvantageously reducing the operating speed of the entire system.

### SUMMARY OF THE INVENTION

The present invention provides a FIFO memory for use with read and write pointers and read and write clock signals. The FIFO memory includes a write counter for updating the write pointer in accordance with the write clock signal and a read counter for updating the read pointer in accordance with the read clock signal. A memory is connected to the write counter and the read counter and has a plurality of memory cells. The memory performs a write operation for writing data to a memory cell corresponding to the write pointer, and a read operation for reading data from a memory cell corresponding to the read pointer. A full flag control circuit indicates a memory full condition by generating a full flag synchronously with the write clock signal when the current read pointer and the next write pointer match. An empty flag control circuit indicates a memory empty condition by generating an empty flag synchronously with the read clock signal when the current write pointer and the next read pointer match.

The present invention also provides a FIFO memory for use with read and write pointers and read and write clock signals. The FIFO memory includes a write counter for updating the write pointer in accordance with the write clock signal and a read counter for updating the read pointer in accordance with the read clock signal. A memory is connected to the write counter and the read counter and has a plurality of memory cells. The memory performs a write operation for writing data to a memory cell corresponding to the write pointer, and a read operation for reading data from a memory cell corresponding to the read pointer. A full flag control circuit indicates a memory full condition by generating a full flag synchronously with the write clock signal when the current read pointer and the next write pointer match, and cancels the full flag synchronously with the write clock signal when the current read pointer and the current write pointer do not match. An empty flag control circuit indicates a memory empty condition by generating an empty flag synchronously with the read clock signal when the current write pointer and the next read pointer match, and cancels the empty flag synchronously with the read clock signal when the current read pointer and the current write pointer do not match.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a block circuit diagram showing a conventional FIFO memory;

FIG. 2 is a block circuit diagram showing the FIFO memory of a first embodiment of the present invention;

FIG. 3 is a block circuit diagram showing the counters of the memory of FIG. 2;

FIG. 4 is a circuit diagram showing the comparison circuit of the memory of FIG. 2;

FIG. 5 is a block circuit diagram showing the full flag generation/cancellation circuit of the memory of FIG. 2;

FIG. 6 is a block circuit diagram of the comparison result determination circuit of the full flag generation/cancellation circuit of FIG. 5;

FIG. 7 is a block circuit diagram showing the flag output circuit of the full flag generation/cancellation circuit of FIG. 5;

FIG. 8 is a block circuit diagram of the empty flag generation/cancellation circuit of the memory of FIG. 2;

FIG. 9 is a block circuit diagram showing a modification of the comparison result determination circuit;

FIG. 10 is an operation waveform chart of the full flag generation/cancellation circuit of FIG. 5;

FIG. 11 is an operation waveform chart of the full flag generation/cancellation circuit of FIG. 5;

FIG. 12 is an operation waveform chart of the empty flag generation/cancellation circuit of FIG. 8;

FIG. 13 is an operation waveform chart of the empty flag generation/cancellation circuit of FIG. 8;

FIG. 14 is a block circuit diagram showing the FIFO memory of a second embodiment of the present invention; and

FIG. 15 is a block circuit diagram showing the FIFO memory of a third embodiment of the present invention.

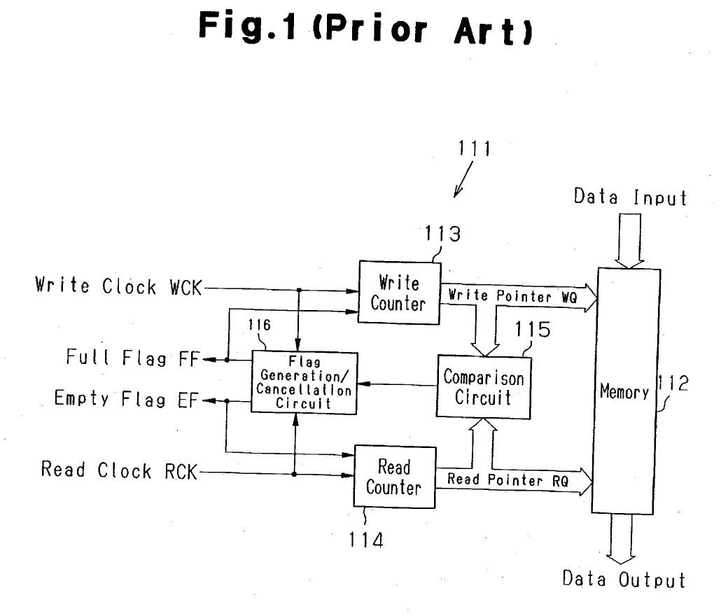

### DETAILED DESCRIPTION OF THE PREFERRED EMBODIMENTS

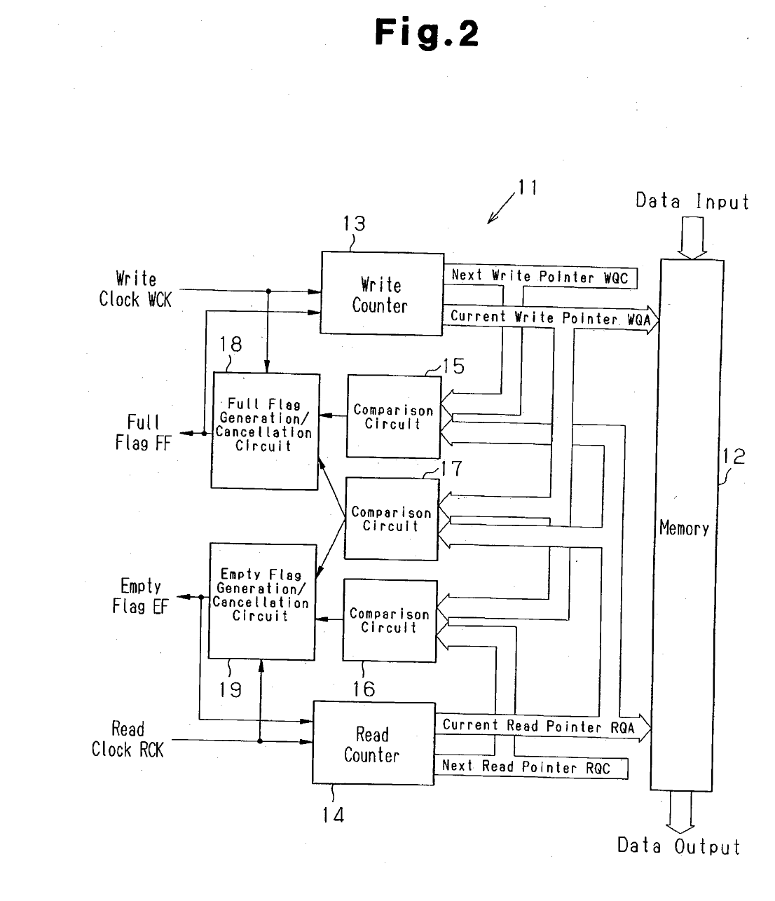

A first embodiment of the present invention is described hereinafter with reference to FIGS. 2 through 13.

FIG. 2 is a block circuit diagram showing the structure of the FIFO memory of a first embodiment of the present invention.

The FIFO memory 11 is provided, for example, between two systems, not shown in the drawings, which transfer data. Furthermore, the systems (the system on the data sending side and the system on the data receiving side) connected to the FIFO memory have mutually different operating frequencies, and both systems respectively operate asynchronously. The FIFO memory 11 is preferably installed in a semiconductor device.

The FIFO memory 11 is provided with a memory 12, write counter 13, a read counter 14, first through third comparison circuits 15 through 17, a full flag generation/cancellation circuit 18, and an empty flag generation/cancellation circuit 19. Furthermore, an initialization circuit and initialization signal (reset signal) for initially setting the FIFO memory are omitted from this same drawing.

The memory 12 is a two-port memory having a write port and a read port (neither is shown in the drawing). The memory 12 writes data output from one system (data sending side) through the write port, and reads the data stored in the memory 12 in the write sequence and supplies the data to the other system (data receiving side) through the read port.

The write counter 13 inputs a write clock signal WCK specifying the operating frequency of the system on the data sending side, and generates a current write pointer WQA indicating the address in the memory 12 for data writing, and a next write pointer WQC indicating the address in the memory 12 for a next data writing.

Specifically, the write counter 13 respectively increments the current write pointer WQA and the next write pointer WQC each time a write clock signal WCK is input, and supplies the current write pointer WQA to the memory 12. In this way, the memory 12 writes data to a memory cell (not shown in the drawing) at the address corresponding to the current write pointer WQA.

Similarly, the read counter 14 inputs a read clock signal RCK specifying the operating frequency of the system on the data receiving side, and generates a current read pointer RQA indicating the address in the memory 12 for data reading, and a next read pointer RQC indicating the address in the memory 12 for a next data reading.

Specifically, the read counter 14 respectively increments the current read pointer RQA and the next read pointer RQC each time a read clock signal RCK is input, and supplies the current read pointer RQA to the memory 12. In this way, the memory 12 reads data from the memory cell (not shown in the drawing) at the address corresponding to the current read pointer RQA.

The write counter 13 is a ring counter which again outputs the initial write pointer WQA after a predetermined number of write pointers WQA have been output. Similarly, the read counter 14 is a ring counter which again outputs the initial read pointer RQA after a predetermined number of read pointers RQA have been output (The number of counts of the counters 13 and 14 are identical).

The first comparison circuit 15 compares the next write pointer WQC output from the write counter 13 and the current read pointer RQA output from the read counter 14, and detects the condition when the pointers WQC and RQA mutually match.

The second comparison circuit 16 compares: the current write pointer WQA output from the write counter 13 and the next read pointer RQC output from the read counter 14, and detects the condition when the pointers WQA and RQC mutually match.

The third comparison circuit 17 compares the current write pointer WQA output from the write counter 13 and the current read pointer RQA output from the read counter 14, and detects the condition when the pointers WQA and RQA do not mutually match.

The full flag generation/cancellation circuit 18 generates and cancels a full flag FF, which indicates that the data stored in the memory 12 is in a full condition, based on a signal output from the first and third comparison circuits 15 and 17.

Specifically, when a write clock signal WCK is input while the first comparison circuit 15 outputs a signal indicating that the next write pointer WQC and the current read pointer RQA match, the full flag generation/cancellation circuit 18 generates a full flag FF in response thereto. Furthermore, when a write clock signal WCK is input while the third comparison circuit 17 outputs a signal indicating that the current write pointer WQA and the current read pointer RQA do not match, the full flag generation/cancellation circuit 18 cancels the full flag FF in response thereto (i.e., the full flag FF output stops).

The empty flag generation/cancellation circuit 19 generates and cancels an empty flag EF, which indicates that the data stored in the memory 12 is in an empty condition, based on the output from the second and third comparison circuits 16 and 17.

Specifically, when a read clock signal RCK is input while the second comparison circuit 16 outputs a signal indicating that the next read pointer RQC and the current write pointer WQA match, the empty flag generation/cancellation circuit 19 generates an empty flag EF in response thereto. Furthermore, when a read clock signal RCK is input while the third comparison circuit 17 outputs a signal indicating that the current write pointer WQA and the current read pointer RQA do not match, the empty flag generation/cancellation circuit 19 cancels the empty flag EF in response thereto (i.e., the empty flag EF output stops).

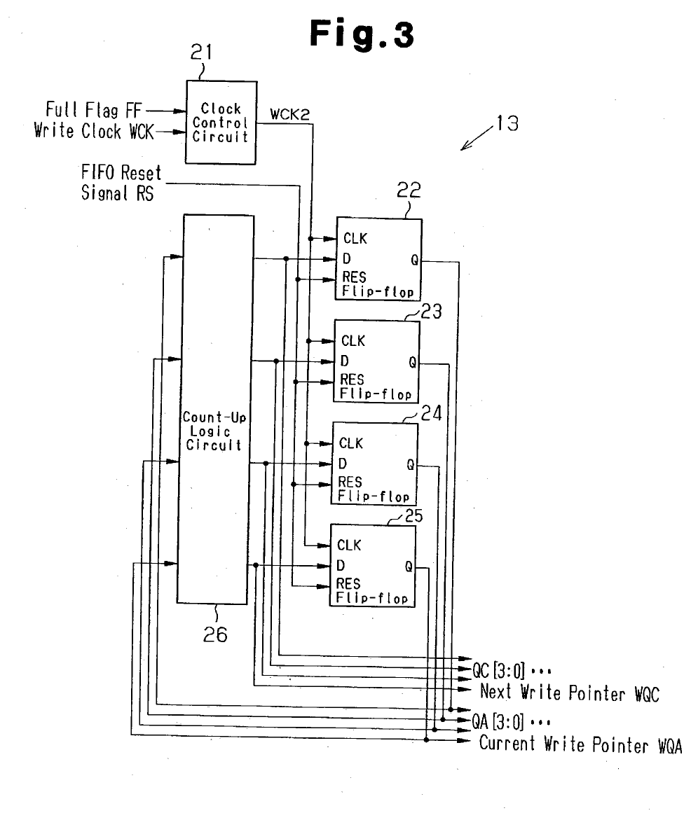

Each circuit of the FIFO memory 11 is described below. FIG. 3 is a block circuit diagram showing an example of the structure of the write counter 13. Furthermore, since the read counter 14 has a structure identical to that of the write counter 13, a detailed description is omitted herefrom.

In the first embodiment, the write counter 13 generates each pointer indicating, for example, a 4-bit address (current write pointer WQA and next write pointer WQC). The write counter 13 includes a clock control circuit 21, first through fourth flip-flop circuits 22 through 25, and count-up logic circuit 26.

When a write clock signal WCK and a full flag FF output from the full flag generation/cancellation circuit 18 are input, the clock control circuit 21 generates a write control clock signal WCK2 in which the write clock signal WCK is controlled by the full flag FF. Furthermore, in the first embodiment, the write clock signal WCK is a free-running clock signal (as is the read clock signal RCK), and the clock control circuit 21 generates the write control clock signal WCK2 so as to stop the write clock signal WCK during a full flag FF is generated.

The first through fourth flip-flop circuits 22 through 25 input the write control clock signal WCK2 to the clock input terminal CLK, input a FIFO reset signal RS to the reset input terminal RES, and input the output signal of the count-up logic circuit 26 to the data input terminal D. Each flip-flop circuits 22 through 25 receives a pointer signal QC output from the count-up logic circuit 26 in response to the write control clock WCK2, and outputs a pointer signal QA from the data output terminal Q. Then, the write counter 13 outputs the 4-bit address formed by the pointer signals QA as the current write pointer WQA.

The count-up logic circuit 26 receives each pointer signal QA output from the flip-flop circuits 22 through 25, and outputs each pointer signal QC generated so as to increment the current write pointer WQA (i.e., address). Then, the write counter 13 outputs the 4-bit address formed by these pointer signals QC as the next write pointer WQC.

The write counter 13 is initialized by the FIFO reset signal RS input to each flip-flop circuit 22 through 25. Furthermore, as described above, the write counter 13 is constructed as a ring counter, and as such again outputs the initial write pointer WQA after a predetermined number of write pointers WQA have been output.

The structures of the first through third comparison circuits 15 through 17 are described below.

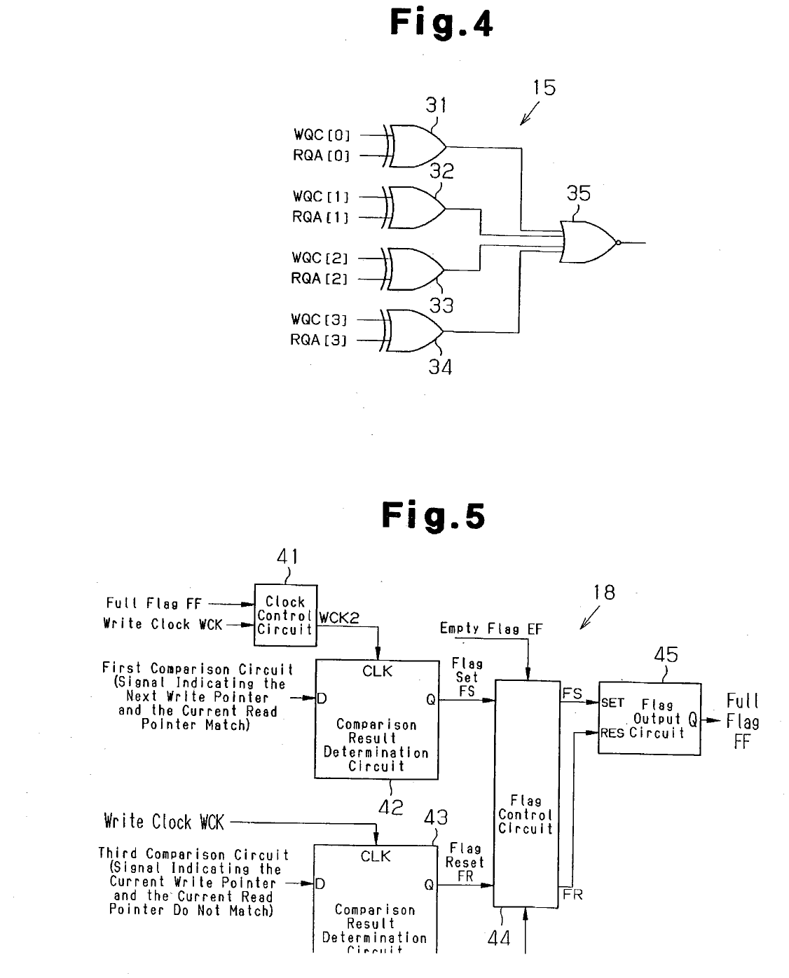

FIG. 4 is a circuit diagram showing an example of the structure of the first comparison circuit 15. The first comparison circuit 15 includes first through fourth E-OR (Exclusive OR) circuits 31 through 34, and a NOR circuit 35.

Bit-position pointer signals WQC [0] through [3] and RQA [0] through [3] respectively corresponding to the next write pointer WQC output from the write counter 13 and the current read pointer RQA output from the read counter 14 are input to the E-OR circuits 31 through 34. Then, the E-OR circuits 31 through 34 output L (low)-level signals when the pointer signals WQC [0] through [3] and RQA [0] through [3] mutually match, and conversely output H (high)-level signals when the pointer signals WQC [0] through [3] and RQA [0] through [3] do not match.

The NOR circuit 35 outputs an H-level signal when the signals output from the E-OR circuits 31 through 34 are all L-level signals. That is, the first comparison circuit 15 outputs an H-level signal when the next write pointer WQC and the current read pointer RQA match. Conversely, the NOR circuit 35 outputs an L-signal when at least one signal among the signals output from the E-OR circuits 31 through 34 is an H-level signal. That is, the first comparison circuit 15 outputs an L-level signal when the next write pointer WQC and the current read pointer RQA do not match.

The second comparison circuit 16 has a structure identical to that of the first comparison circuit 15. That is, the second comparison circuit 16 outputs an H-level signal when the current write pointer WQA and the next read pointer RQC match, and conversely outputs an L-level signal when the two pointers WQA and RQC do not match.

The third comparison circuit 17 has a structure provided with an OR circuit (not shown in the drawings) in place of the NOR circuit 35 used in the first comparison circuit 15. That is, the third comparison circuit 17 outputs an L-level signal when the current write pointer WQA and the current read pointer RQA match, and conversely outputs an H-level signal when the two pointers WQA and RQA do not match.

FIG. 5 is a block circuit diagram showing an example of the structure of the full flag generation/cancellation circuit 18. The full flag generation/cancellation circuit 18 includes a clock control circuit 41, first and second comparison result determination circuits 42 and 43, a flag control circuit 44, and a flag output circuit 45.

The clock control circuit 41 has a structure identical to that of the clock control circuit 21 provided in the previously described write counter 13, and, while the full flag is generated, generates a write control clock signal WCK2 so as to stop the write clock signal WCK.

The first comparison result determination circuit 42 receives the output signal from the first comparison circuit 15 simultaneously with the write control clock signal WCK2. Specifically, the first comparison result determination circuit 42 outputs a flag set signal FS when a write control clock signal WCK2 is input while a signal indicating that the next write pointer WQC and the current read pointer RQA match (specifically, an H-level signal output from the first comparison circuit 15) is input.

The second comparison result determination circuit 43 receives the output signal from the third comparison circuit 17 synchronously with the write clock signal WCK. Specifically, the second comparison result determination circuit 43 outputs a flag reset signal FR when a write clock signal WCK is input while a signal indicating that the current write pointer WQA and the current read pointer RQA do not match (specifically an H-level signal output from the third comparison circuit 17) is input.

The flag control circuit 44 outputs the flag set signal FS and the flag reset signal FR to the flag output circuit 45. The flag control circuit 44 is initialized by the FIFO reset signal RS. Furthermore, the flag control circuit 44 stops the output of the flag set signal FS and the flag reset signal FR by the empty flag EF output from the empty flag generation/cancellation circuit 19. That is, the flag control circuit 44 prevents the output of a full flag FF from the full flag generation/cancellation circuit 18 when an empty flag EF is output from the empty flag generation/cancellation circuit 19.

The flag output circuit 45 outputs the full flag FF in response to the flag set signal FS output from the flag control circuit 44. Then, in this condition, when a flag reset signal FR is output from the flag control circuit 44, the flag output circuit 45 stops the output of the full flag FF in response thereto.

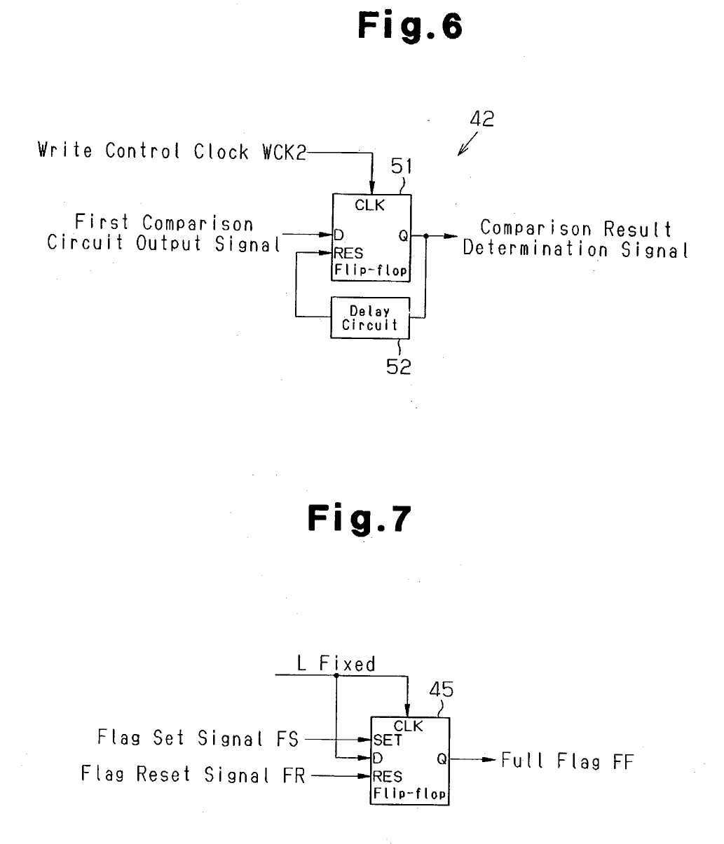

FIG. 6 is a block circuit diagram showing a specific example of the first comparison result determination circuit 42. Furthermore, since the second comparison result determination circuit 43 has a structure identical to that of the first comparison result determination circuit 42, detailed description is omitted herefrom.

The first comparison result determination circuit 42 includes a flip-flop circuit 51 and a delay circuit 52. The flip-flop circuit 51 inputs the write control clock signal WCK2 to the clock input terminal CLK, and inputs the output signal from the first comparison circuit 15 to the data input terminal D. Furthermore, the signal output from the data output terminal D is input to the reset input terminal RES through the delay circuit 52. Accordingly, when a write control clock signal WCK2 is input while a signal indicating that the next write pointer WQC and the current read pointer RQA match is input, the first comparison result determination circuit 42 outputs an H-level flag set signal FS having a pulse width corresponding to the delay time of the delay circuit 52.

FIG. 7 is a block circuit diagram showing the specific structure of the flag output circuit 45.

The flag output circuit 45 is a typical flip-flop circuit having a set input terminal SET and a reset input terminal RES, wherein the flag set signal FS is input to the set input terminal SET, and the flag reset signal FR is input to the reset input terminal RES. For example, L-level signals are input to the clock input terminal CLK and the data input terminal D of this flip-flop circuit. Accordingly, the flag output circuit 45 outputs a full flag FF in response to the H-level flag set signal FS (i.e., an H-level signal is output from the flip-flop circuit). Then, in this condition, the flag output circuit 45 cancels the full flag FF in response to an H-level flag reset signal FR (i.e., an L-level signal is output from the flip-flop circuit).

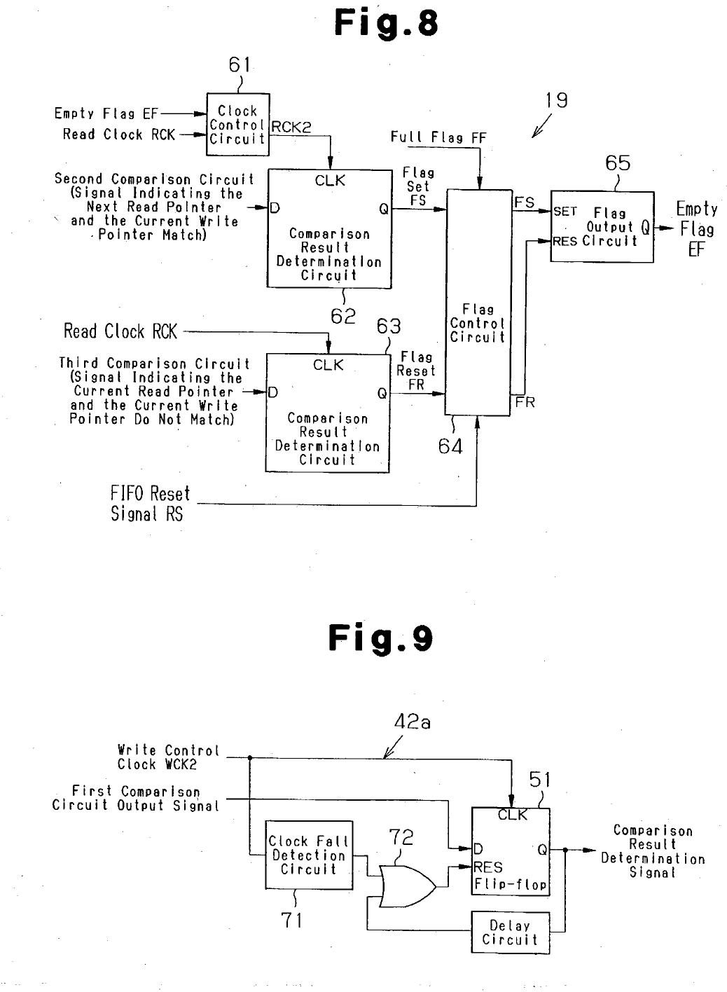

FIG. 8 is a block circuit diagram showing an example of the structure of the empty flag generation/cancellation circuit 19. The empty flag generation/cancellation circuit 19 includes a clock control circuit 61, first and second comparison result determination circuits 62 and 63, a flag control circuit 64, and a flag output circuit 65. Furthermore, since the operation of the empty flag generation/cancellation circuit 19 is identical to the operation of the full flag generation/cancellation circuit 18, detailed description is omitted herefrom.

That is, the empty flag generation/cancellation circuit 19 outputs an empty flag EF when a read control clock signal RCK2 is input while a signal is input that indicates the next read pointer RQC and the current write pointer WQA match (specifically, an H-level signal output from the second comparison circuit 16). Conversely, the empty flag generation/cancellation circuit 19 stops the output of the empty flag EF when a read clock signal RCK is input while a signal is input that indicates the current read pointer RQA and current write pointer WQA do not match (specifically, an H-level signal output from the third comparator 17).

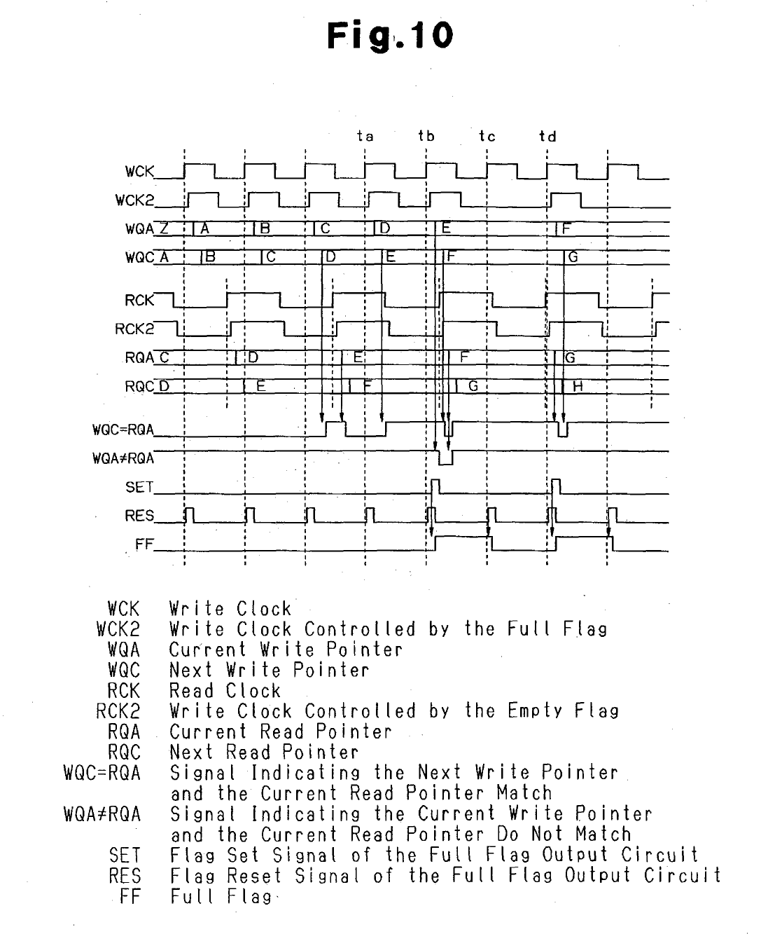

The operation of the FIFO memory 11 is described below. FIG. 10 is an operation waveform chart of the full flag generation/cancellation circuit 18. Furthermore, this operation waveform chart illustrates the condition when the empty flag EF is not generated.

Now, the write control clock signal WCK2 rises in response to the rise of the write clock signal WCK at time ta. In response to the rise of the write control clock signal WCK2, the write counter 13 increments the current write pointer WQA and the next write pointer WQC, and respectively outputs a current write pointer WQA having a value [D] and a next write pointer WQC having a value [E]. In this way, the memory 12 writes data to the memory cell at the address corresponding to the current write pointer WQA having the value [D].

Furthermore, at this time, the current read pointer RQA has a value [E], and the memory 12 reads the data from the memory cell at the address corresponding to this pointer. Accordingly, the next write pointer WQC (“E”) and the current read pointer RQA (“E”) match, and the first comparison circuit 15 detects the condition of the matching pointers (WQC=RQA), and outputs an H-level signal.

Next, the write control clock signal WCK2 rises in response to the rise of the write clock signal WCK at time tb. In response to the rise of the write control clock signal WCK2, the first comparison result determination circuit 42 of the full flag generation/cancellation circuit 18 outputs a flag set signal FS having a predetermined pulse width, the flag control circuit 44 outputs this flag set signal FS to the set input terminal SET of the flag output circuit 45. Accordingly, the flag output circuit 45 outputs a full flag FF (i.e., the flag output circuit 45 outputs a H-level signal).

Furthermore, in response to the rise of the write control clock signal WCK2, the write counter 13 increments the current write pointer WQA and the next write pointer WQC, and respectively outputs a current write pointer WQA having a value [E] and a next write pointer WQC having a value [F]. In this way, the memory 12 writes data to the memory cell at the address corresponding to the current write pointer WQA having the value [E].

Thereafter, the read control clock signal RCK2 rises in response to the rise of the read clock signal RCK. In response to the read control clock signal RCK2, the read counter 14 increments the current read pointer RQA and the next read pointer RQC, and respectively outputs a current read pointer RQA having a value [F] and a next read pointer RQC having a value [G]. In this way, the memory 12 read data from the memory cell at the address corresponding to the current read pointer RQA having the value [F].

Then, at time tc, a write clock signal WCK is input when the full flag FF is generated (i.e., when an H-level signal is output from the flag output circuit 45). This time, the clock control circuit 21 of the write counter 13 stops the output of the write control clock signal WCK2. Accordingly, the current write pointer WQA (“E”) and the next write pointer WQC (“F”) are not updated, and the write operation is not performed.

Furthermore, at time tc, the current write pointer WQA (“E”) and the current read pointer RQA (“F”) do not match. This time, the third comparison circuit 17 detects the pointer mismatch (WQA≠RQA), and outputs an H-level signal. Accordingly, the second comparison result determination circuit 43 of the full flag generation/cancellation circuit 18 outputs a flag reset signal FR having a predetermined pulse width in response to the rise of the write clock signal WCK, and the flag control circuit 44 outputs this flag reset signal FR to the reset input terminal RES of the flag output circuit 45. Accordingly, the flag output circuit 45 cancels the full flag FF (i.e., the flag output circuit 45 outputs an L-level signal).

In this way, the full flag FF is generated when a write control clock signal WCK2 is input when the next write pointer WQC and the current read pointer RQA match. Then, the generated full flag FF is cancelled when a write clock signal WCK is input when the current write pointer WQA and the current read pointer RQA do not match. Accordingly, the output delay of the full flag FF is determined only by the delay of the full flag generation/cancellation circuit 18.

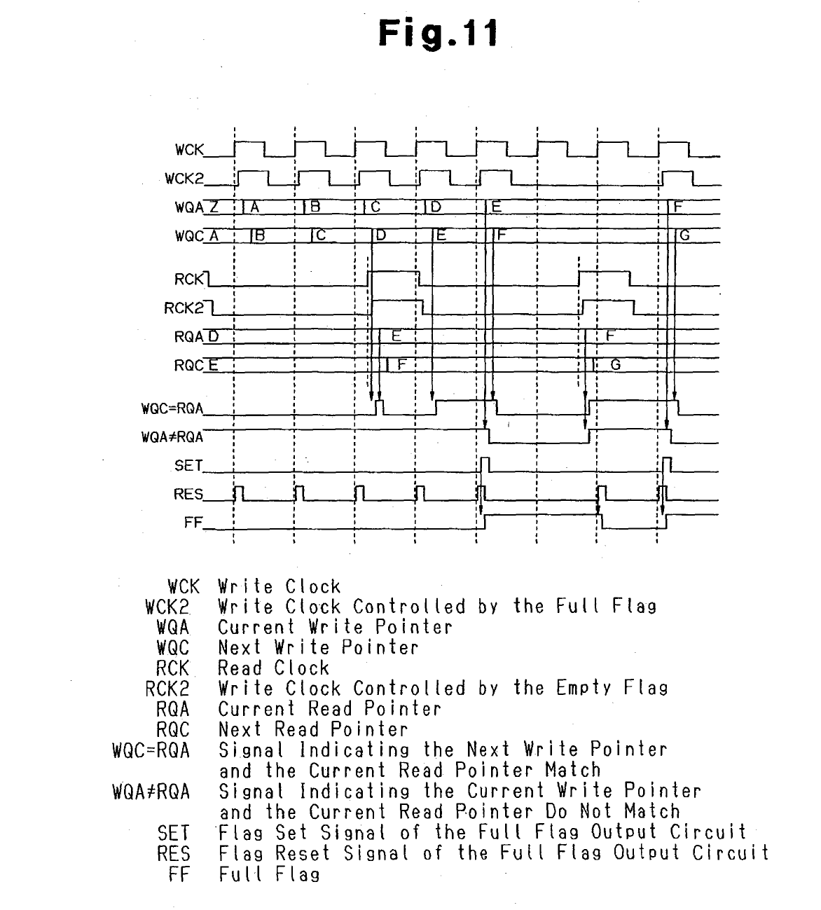

FIG. 11 is another operation waveform chart of the full flag generation/cancellation circuit 18. This operation waveform chart illustrates the situation when the frequency of the read clock signal RCK is lower than the frequency of the read clock signal RCK shown in FIG. 10; in this case, the generation time of the full flag FF is lengthened (i.e., the time during which the write operation is prohibited is lengthened). In this case also, the output delay of the full flag FF is determined only by the delay of the full flag generation/cancellation circuit 18 in the same manner as described above.

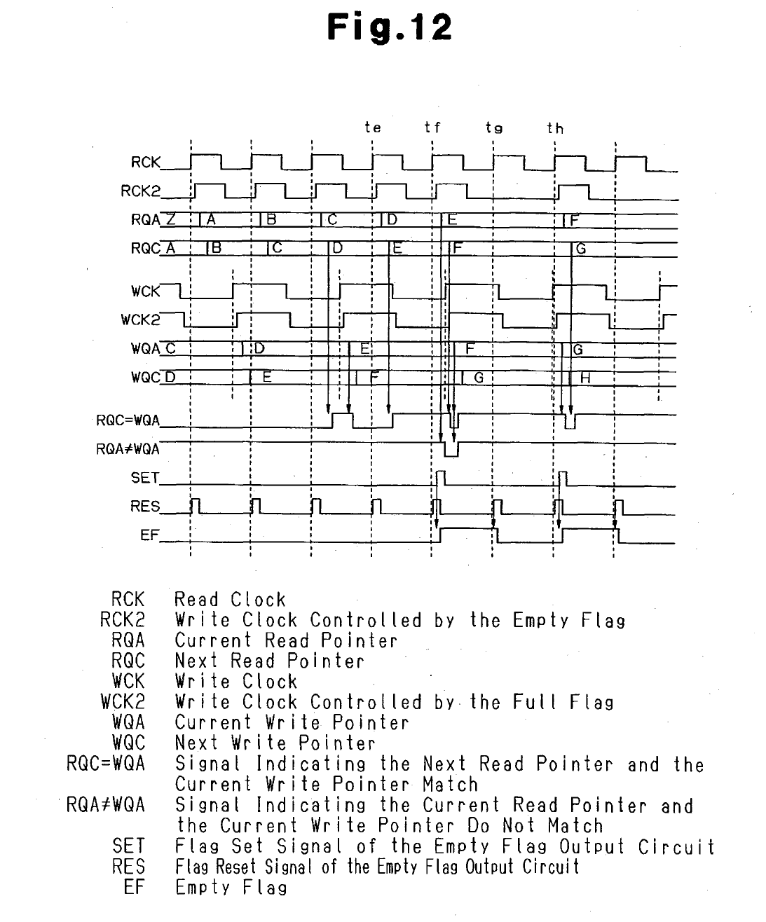

FIG. 12 is an operation waveform chart of the empty flag generation/cancellation circuit 19. This operation waveform chart illustrates the situation when the full flag FF has not been generated.

In the first embodiment, the operation of the empty flag generation/cancellation circuit 19 is identical to the operation of the full flag generation/cancellation circuit 18. Therefore, detailed description is omitted herefrom.

That is, as shown in FIG. 12, the empty flag EF is generated when a read control clock signal RCK2 is input when the next read pointer RQC and the current write pointer WQA match (in the drawing, for example, when the read clock signal RCK is input at time tf). Then, the generated empty flag EF is cancelled when a read clock signal RCK is input when the current write pointer WQA and the current read pointer RQA do not match (in the drawing, for example, when the read clock signal RCK is input at time tg). Accordingly, the output delay of the empty flag EF is determined only by the delay of the empty flag generation/cancellation circuit 19.

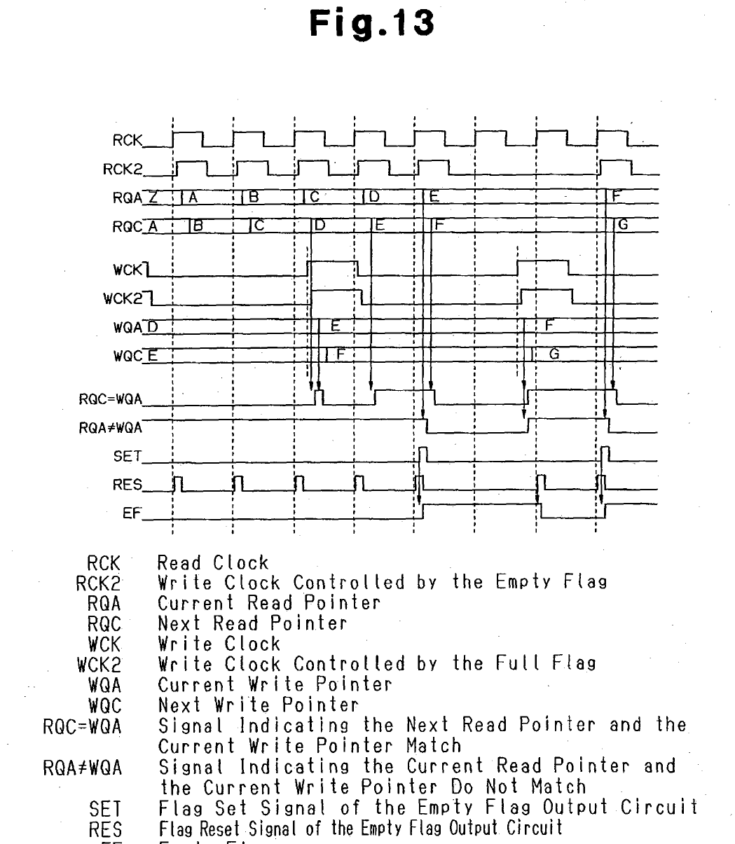

FIG. 13 is another operation waveform chart of the empty flag generation/cancellation circuit 19. This operation waveform chart illustrates the situation when the frequency of the write clock signal WCK is less than the frequency of the write clock signal WCK shown in the previously mentioned FIG. 12; in this case, the generation time of the empty flag EF is lengthened (i.e., the time during which the reading operation is prohibited is lengthened). In this case also, the delay time of the empty flag EF is determined only by the delay of the empty flag generation/cancellation circuit 19, as in the previously described case.

Furthermore, in the FIFO memory 11 of the first embodiment, the first comparison result determination circuit 42 provided in the full flag generation/cancellation circuit 18 also may be modified as shown in FIG. 9. Although detailed description is omitted, the other second comparison result determination circuit 43, and the first and second comparison result determination circuits 62 and 63 provided in the empty flag generation/cancellation circuit 19 may be similarly modified.

As shown in FIG. 9, the comparison result determination circuit 42a includes a flip-flop circuit 51, a delay circuit 52, a clock fall detection circuit 71 as an initialization circuit, and an OR circuit 72.

The clock fall detection circuit 71 detects the fall of the write control clock signal WCK2, and generates a pulse signal. When a pulse signal is output from the clock fall detection circuit 71, the OR circuit 72 outputs a signal for forcibly resetting the flip-flop circuit 51 to the reset input terminal RES regardless of the signal output from the delay circuit 52.

In such a comparison result determination circuit 42a, even when the flip-flop circuit 51, for example, is in a metastable state (state wherein output oscillates or becomes unstable such as when an intermediate electric potential is fixed), this state does not continue until the next clock signal (write control clock signal WCK2) rises. In this way, the operation of the comparison result determination circuit 42a can be stabilized, and erroneous operation of the FIFO can be reliably prevented.

By way of detailed explanation, when the flip-flop circuit 51 receives the output signal of the first comparison circuit 15 (a signal indicating that the next write pointer WQC and the current read pointer RQA match) synchronously with the rise of the write control clock signal WCK2, there is a possibility that the signal output from the first comparison circuit 15 may be undergoing a change.

That is, in the data transfer occurring between a high-speed operating system and a low-speed operating system, the data writing operation and the data reading operation are performed asynchronously, as described above. Therefore, the next write pointer WQC and the current read pointer RQA are matched by either the write clock signal WCK or the read clock signal RCK. Accordingly, when the flip-flop circuit 51 receives the output signal of the first comparison circuit 15 synchronously with the rise of the write control clock signal WCK2, there is a possibility that the next write pointer WQC and the current read pointer RQA are in a matched condition, or undergoing a change to an opposite condition. When the signal in this condition is received by the flip-flop circuit 51, the flip-flop circuit 51 becomes unstable and enters a metastable state.

In the above-mentioned comparison result determination circuit 42a shown in FIG. 9, the fall of the write control clock signal WCK2 forcibly resets the flip-flop circuit 51 even when in the aforesaid metastable condition. In this way, the flip-flop circuit 51 can stably operate with the subsequent rise of the write control clock signal WCK2.

As previously described, the first embodiment provides the advantages mentioned below.

(1) When a write control clock signal WCK2 is input while the next write pointer WQC and the current read pointer RQA match, the full flag generation/cancellation circuit 18 generates a full flag FF in response thereto. In this way, the output delay of the full flag FF is determined only by the delay of the full flag generation/cancellation circuit 18, such that the full flag FF can be rapidly generated even when the memory 12 is in a full capacity condition. Accordingly, overflow generation can be reliably prevented while maintaining the frequency of the write clock signal (operating frequency of the system on the data sending side) at a high frequency.

(2) When a write clock signal WCK is input while the current read pointer RQA and the current write pointer WQA do not match, the full flag generation/cancellation circuit 18 cancels the full flag in response thereto. Accordingly, the full flag FF can also be rapidly cancelled.

(3) When a read control clock signal RCK2 is input while the next read pointer RQC and the current write pointer WQA match, the empty flag generation/cancellation circuit 19 generates an empty flag EF in response thereto. In this way, the delay of the empty flag EF is determined only by the delay of the empty flag generation/cancellation circuit 19, such that the empty flag EF can be rapidly generated even when the memory 12 is in an empty condition. Accordingly, underflow generation can be reliably prevented while maintaining the frequency of the read clock signal RCK at a high frequency (operating frequency of the system on the data receiving side).

(4) When a read clock signal RCK is input while the current read pointer RQA and the current write pointer WQA do not match, the empty flag generation/cancellation circuit 19 cancels the empty flag EF in response thereto. Accordingly, the empty flag can also be rapidly cancelled.

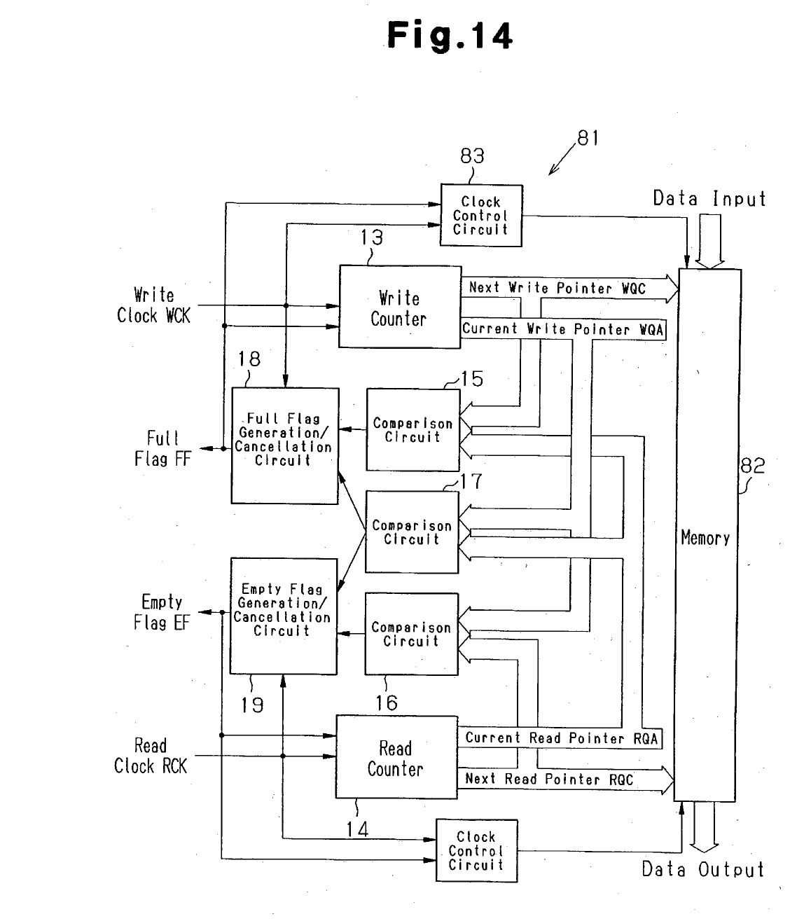

A second embodiment of the present invention is described below with reference to FIG. 14.

FIG. 14 is a block circuit diagram showing the FIFO memory of a second embodiment of the present invention. The FIFO memory 81 of the second embodiment has a structure in which the memory 12 of the FIFO memory 11 of the first embodiment is modified to the clock synchronized-type memory 82, and is provided with additional clock control circuits 83 and 84. Accordingly, like structural parts are referred to by like reference numbers, and detailed descriptions of these like parts are omitted.

A next write pointer WQC generated by the write counter 13 is input to a first address decoder (not shown in the drawing) provided within the memory 82, and a next read pointer RQC generated by the read counter 14 is input to a second address decoder (not shown in the drawing) provided within the memory 82.

The clock control circuit 83 supplies a write control clock signal WCK2 generated based on the full flag FF to a first address decoder provided within the memory 82, although not shown in the drawing. The first address decoder selects an address (memory cell) for writing data in response to the write control clock signal WCK2.

Similarly, the clock control circuit 84 supplies a read control clock signal RCK2 generated based on the empty flag EF to a second address decoder provided within the memory 82, and also not shown in the drawing. The second address decoder selects an address (memory cell) for reading data in response to the read control clock signal RCK2.

By way of detailed explanation, the write counter 13 generates a current write pointer WQA and a next write pointer WQC in response to the input write control clock signal WCK2, and outputs the generated next write pointer WQC to the first address decoder of the memory 82. That is, the write counter 13 notifies the memory 82 of the next write pointer WQC beforehand, during the cycle of the current write operation. In this way, the memory 82 is prepared to write data of the next cycle to the memory cell at the address corresponding to the next write pointer WQC of which it was notified.

Thereafter, when a write control clock signal WCK2 is input, the memory 82 writes data to the memory cell at the address corresponding to the pointer WQC of which it was notified beforehand, and at the same time the write counter 13 similarly outputs a next write pointer WQC to the memory 82. Furthermore, although this description pertains to the write operation, the read operation is performed similarly.

Therefore, the second embodiment provides the following advantages.

(1) The delay time of the write operation (time until the writing of data to the memory 82 is completed) is the only time during which data is written to the memory cell at the address selected beforehand by the first address decoder. That is, in the second embodiment, the write operation is unaffected by the delay time of the write counter 13 and the delay time of the first address decoder. Accordingly, the write operation can be performed at high speed.

(2) The delay time of the read operation (time until the reading of data from the memory 82 is completed) is only the time during which data is read from the memory cell at the address selected beforehand by the second address decoder. That is, in the second embodiment, the read operation is unaffected by the delay time of the read counter 14 and the delay time of the second address decoder. Accordingly, the read operation can be performed at high speed.

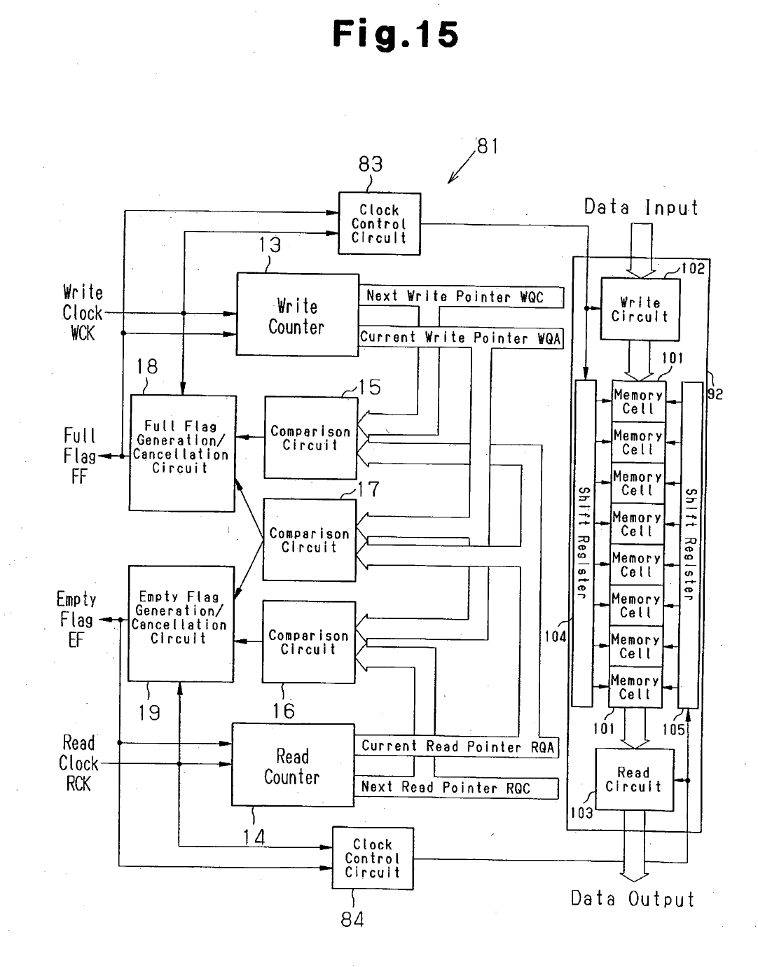

A third embodiment of the present invention is described below with reference to FIG. 15.

FIG. 15 is a block circuit diagram of the FIFO memory of a third embodiment. The FIFO memory 91 of the third embodiment provides a modification of part of the memory 82 in the FIFO memory 81 of the second embodiment. Therefore, like structural parts are referred to by like reference numbers, and detailed descriptions of these like parts are omitted.

As shown in the drawing, the memory 92 of the third embodiment includes a plurality of memory cells 101, a write circuit 102, a read circuit 103, and first and second shift registers 104 and 105.

In the write operation in this memory 92, the first shift register 104 sequentially selects memory cells 101 synchronously with the write control clock signal WCK2, and the write circuit 102 writes data to the selected memory cell 101. In the read operation, however, the second shift register 105 sequentially selects memory cells 101 synchronously with the read control clock signal RCK2, and the read circuit 103 reads data from the selected memory cell 101.

According to the third embodiment, the address decoders for selecting addresses in the memory 92 when writing and reading data may be omitted from the memory 92. Therefore, the write operation and the read operation can be performed at high speed. Furthermore, since the shift registers 104 and 105 generally have smaller surface areas than the address decoders, the circuit layout of the FIFO memory 11 can be made more compact.

It should be apparent to those skilled in the art that the present invention may be embodied in many other specific forms without departing from the spirit or scope of the invention. Particularly, it should be understood that the invention may be embodied in the following forms.

Although each embodiment is structured such that the full flag FF and empty flag EF are generated synchronously with the rise of the write control clock signal WCK2 and read control clock signal RCK2, they may also be structured such that the full flag FF and empty flag EF are generated synchronously with the fall of the clock signals WCK2 and RCK2.

When the full flag FF and empty flag EF are generated synchronously with the fall of the clock signals WCK2 and RCK2, the structure may provide a clock rise detection circuit for detecting the edge of the rise of the next clock signals WCK2 and RCK2 in place of the clock fall detection circuit 71.

The structures of the write counter 13 and read counter 14 are not limited to the structures in the embodiments.

Furthermore, the structures of the first through third comparison circuits 15 through 17 are not limited to the structures of the embodiments. That is, the comparison circuits 15 through 17 may have structures capable of detecting whether or not two input pointers (addresses) match.

Therefore, the present examples, and embodiments are to be considered as illustrative and not restrictive and the invention is not to be limited to the details given herein, but may be modified within the scope and equivalence of the appended claims.

What is claimed is:

1. A FIFO memory for use with read and write pointers and read and write clock signals, the FIFO memory comprising:
a write counter for updating the write pointer in accordance with the write clock signal;
a read counter for updating the read pointer in accordance with the read clock signal;
a memory connected to the write counter and the read counter and having a plurality of memory cells, the memory performing a write operation for writing data to a memory cell corresponding to the write pointer, and a read operation for reading data from a memory cell corresponding to the read pointer;
a full flag control circuit for indicating a memory full condition by generating a full flag synchronously with the write clock signal when the current read pointer and the next write pointer match; and
an empty flag control circuit for indicating a memory empty condition by generating an empty flag synchronously with the read clock signal when the current write pointer and the next read pointer match.

2. The FIFO memory of claim 1, further comprising:
a first comparison circuit connected to the write counter and the read counter, for comparing the current read pointer and the next write pointer, and generating a first signal for generating the full flag in the full flag control circuit when the current read pointer and the next write pointer match; and
a second comparison circuit connected to the write counter and the read counter, for comparing the current write pointer and the next read pointer, and generating a second signal for generating an empty flag in the empty flag control circuit when the current write pointer and the next read pointer match.

3. The FIFO memory of claim 2, further comprising:
a third comparison circuit connected to the write counter and the read counter, for comparing the current read pointer and the current write pointer, and generating a third signal to cancel either the full flag in the full flag control circuit or cancel the empty flag in the empty flag control circuit when the current read pointer and the current write pointer do not match.

4. The FIFO memory of claim 3, wherein the full flag control circuit includes a first comparison result determination circuit connected to the third comparison circuit, for receiving the third signal synchronously with the write clock signal, and the empty flag control circuit includes a second comparison result determination circuit connected to the third comparison circuit, for receiving the third signal synchronously with the read clock signal.

5. The FIFO of claim 4, wherein at least one of the first and second comparison result determination circuits includes a flip-flop circuit having a data output terminal for outputting a signal, and a reset input terminal to feed back a signal delayed by a predetermined time, for generating a pulse signal having a pulse width corresponding to the predetermined delay time.

6. The FIFO memory of claim 5, wherein each clock signal has an edge and an opposite edge and at least one of the first and second comparison result determination circuits includes an initialization circuit connected to the flip-flop circuit, for detecting the opposite edge of the edge of the write clock signal or the read clock signal when the flip-flop circuit receives a signal, and generating a reset signal for resetting the flip-flop circuit.

7. The FIFO memory of claim 2, wherein the full flag control circuit includes a first comparison result determination circuit connected to the first comparison circuit, for receiving the first signal synchronously with the write clock signal, the write clock signal being controlled by the full flag, and the empty flag control circuit includes a second comparison result determination circuit connected to the second comparison circuit, for receiving the second signal synchronously with the read clock signal, the read clock signal being controlled by the empty flag.

8. The FIFO memory of claim 7, wherein at least one of the first and second comparison result determination circuits includes a flip-flop circuit having a data output terminal for outputting a signal, and a reset input terminal to feed back a signal delayed by a predetermined time, for generating a pulse signal having a pulse width corresponding to the predetermined delay time.

9. The FIFO memory of claim 8, wherein each clock signal has an edge and an opposite edge and at least one of the first and second comparison result determination circuits includes an initialization circuit connected to the flip-flop circuit, for detecting the opposite edge of the edge of the write clock signal or the read clock signal when the flip-flop circuit receives a signal, and generating a reset signal for resetting the flip-flop circuit.

10. The FIFO memory of claim 1, wherein the write counter includes:
a plurality of flip-flop circuits for generating a current write pointer synchronously with the write clock signal, the write clock signal being controlled by the full flag; and
a count-up logic circuit connected to the plurality of flip-flop circuits, for incrementing the current write pointer and generating a next write pointer.

11. The FIFO memory of claim 1, wherein the read counter includes:
a plurality of flip-flop circuits for generating a current read pointer synchronously with the read clock signal, the read clock signal being controlled by the empty flag; and
a count-up logic circuit connected to the plurality of flip-flop circuits, for incrementing the current read pointer and generating a next read pointer.

12. The FIFO memory of claim 1, wherein the memory performs a write operation in response to the current write pointer supplied from the write counter and performs a read operation in response to the current read pointer supplied from the read counter.

13. The FIFO memory of claim 1, wherein the memory receives beforehand a next write pointer supplied from the write counter and performs a write operation synchronously with the write clock signal, the write clock signal being controlled by the full flag, and receives beforehand a next read pointer supplied from the read counter and performs a read operation synchronously with the read clock signal, the read clock signal being controlled by the empty flag.

14. The FIFO memory of claim 1, wherein the memory comprises:
a first shift register for sequentially selecting memory cells synchronously with the write clock signal, the write signal being controlled by the full flag;
a write circuit connected to the first shift register, for writing data to the memory cell selected by the first shift register;
a second shift register for sequentially selecting memory cells synchronously with the read clock signal, the read clock signal being controlled by the empty flag; and
a read circuit connected to the second shift register, for reading data from the memory cell selected by the second shift register.

15. A FIFO memory for use with read and write pointers and read and write clock signals, the FIFO memory comprising:
a write counter for updating the write pointer in accordance with the write clock signal;
a read counter for updating the read pointer in accordance with the read clock signal;
a memory connected to the write counter and the read counter and having a plurality of memory cells, the memory performing a write operation for writing data to a memory cell corresponding to the write pointer, and a read operation for reading data from a memory cell corresponding to the read pointer;
a full flag control circuit for indicating a memory full condition by generating a full flag synchronously with the write clock signal when the current read pointer and the next write pointer match, and canceling the full flag synchronously with the write clock signal when the current read pointer and the current write pointer do not match; and
an empty flag control circuit for indicating a memory empty condition by generating an empty flag synchronously with the read clock signal when the current write pointer and the next read pointer match, and canceling the empty flag synchronously with the read clock signal when the current read pointer and the current write pointer do not match.

16. A semiconductor device comprising:
a FIFO memory for use with read and write pointers and read and write clock signals, wherein the FIFO memory includes:
a write counter for updating the write pointer in accordance with the write clock signal;
a read counter for updating the read pointer in accordance with the read clock signal;
a memory connected to the write counter and the read counter and having a plurality of memory cells, the memory performing a write operation for writing data to a memory cell corresponding to the write pointer, and a read operation for reading data from a memory cell corresponding to the read pointer;
a full flag control circuit for indicating a memory full condition by generating a full flag synchronously with the write clock signal when the current read pointer and the next write pointer match; and
an empty flag control circuit for indicating a memory empty condition by generating an empty flag synchronously with the read clock signal when the current write pointer and the next read pointer match.

17. A semiconductor device comprising:
a FIFO memory for use with read and write pointers and read and write clock signals, wherein the FIFO memory includes:
a write counter for updating the write pointer in accordance with the write clock signal;
a read counter for updating the read pointer in accordance with the read clock signal;
a memory connected to the write counter and the read counter and having a plurality of memory cells, the memory performing a write operation for writing data to a memory cell corresponding to the write pointer, and a read operation for reading data from a memory cell corresponding to the read pointer;
a full flag control circuit for indicating a memory full condition by generating a full flag synchronously with the write clock signal when the current read pointer and the next write pointer match, and canceling the full flag synchronously with the write clock signal when the current read pointer and the current write pointer do not match; and
an empty flag control circuit for indicating a memory empty condition by generating an empty flag synchronously with the read clock signal when the current write pointer and the next read pointer match, and canceling the empty flag synchronously with the read clock signal when the current read pointer and the current write pointer do not match.
